(19) United States
(12) Patent Application Publication
(10) Pub. No.: US 2023/0015405 A1
(43) Pub. Date: Jan. 19, 2023

(54) BULK ACOUSTIC RESONATOR PACKAGE

(71) Applicant: SAMSUNG ELECTRO-MECHANICS CO., LTD., Suwon-si (KR)

(72) Inventors: Tae Kyung LEE, Suwon-si (KR); Sung Joon PARK, Suwon-si (KR); Kwang Su KIM, Suwon-si (KR); Jae Goon AUM, Suwon-si (KR); Sung HAN, Suwon-si (KR)

(73) Assignee: SAMSUNG ELECTRO-MECHANICS CO., LTD., Suwon-si (KR)

(21) Appl. No.: 17/679,472

(22) Filed: Feb. 24, 2022

(30) Foreign Application Priority Data
Jul. 15, 2021 (KR) 10-2021-0092576

(51) Int. Cl. H03H 9/10; H03H 9/13

(52) U.S. Cl. CPC H03H 9/105; H03H 9/13

(57) ABSTRACT

A bulk acoustic resonator package is provided. The bulk acoustic resonator package includes a substrate; a cap; a resonance portion including a first electrode, a piezoelectric layer, and a second electrode, stacked in a first direction in which the substrate and the cap face each other, and disposed between the substrate and the cap; and a cap melting member disposed to surround the resonance portion, and disposed to be in contact with a portion of a surface of the cap facing the substrate, when viewed in the first direction, and including a material or a structure that is based on a melting of the portion of the surface of the cap.

### CROSS-REFERENCE TO RELATED APPLICATIONS

This application claims the benefit under 35 USC 119(a) of Korean Patent Application No. 10-2021-0092576 filed on Jul. 15, 2021 in the Korean Intellectual Property Office, the entire disclosure of which is incorporated herein by reference for all purposes.

### BACKGROUND

### 1. Field

The following description relates to a bulk acoustic resonator package.

### 2. Description of Related Art

With the recent rapid development of mobile communications devices, chemical and biological testing devices, and similar devices, there is increasing demand for miniature and lightweight filters, oscillators, resonant elements, acoustic resonant mass sensors, and similar elements, implemented in such devices.

A bulk acoustic resonator, such as a bulk acoustic wave (BAW) filter, may be utilized as a device that implements such miniature and lightweight filters, oscillators, resonant elements, acoustic resonant mass sensors, and the like, and may have a significantly small size and improved performance, as compared to a dielectric filter, a metal cavity filter, a waveguide, or the like. Therefore, bulk acoustic resonators have been widely implemented in communications modules of modern mobile devices where it is desirous to have improved performance (for example, a broad pass bandwidth).

The above information is presented as background information only, to assist in gaining an understanding of the present disclosure. No determination has been made, and no assertion is made, as to whether any of the above might be applicable as prior art with regard to the disclosure.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In a general aspect, a bulk acoustic resonator package includes a substrate; a cap; a resonance portion comprising a first electrode, a piezoelectric layer, and a second electrode, stacked in a first direction in which the substrate and the cap face each other, and disposed between the substrate and the cap; and a cap melting member disposed to surround the resonance portion, and disposed to be in contact with a portion of a surface of the cap facing the substrate, when viewed in the first direction, and comprising a material or a structure that is based on a melting of the portion of the surface of the cap.

The bulk acoustic resonator package may further include a support layer disposed between the substrate and the resonance portion, wherein the cap melting member may be disposed to be in contact with the support layer.

The support layer may be configured to provide a cavity that is disposed to be surrounded by the support layer, and at least a portion of the resonance portion may overlap the cavity, when viewed in the first direction.

The support layer may be configured to have a stepped form that provides a space in which the cap melting member is disposed.

The cap may include a glass material, and the support layer may include at least one of polysilicon and amorphous silicon.

The bulk acoustic resonator package may include a support layer disposed between the substrate and the resonance portion; and a membrane layer disposed between the support layer and the resonance portion and including a material that is different from a material included in the support layer, wherein the cap melting member may be disposed to be in contact with the membrane layer.

The cap may include a glass material, and the membrane layer may include at least one of silicon dioxide (SiO₂) and silicon nitride (Si₃N₄).

The bulk acoustic resonator package may include a support layer disposed between the substrate and the resonance portion; and an insulating layer disposed between the support layer and the substrate, and including a material that is different from a material included in the support layer, wherein the cap melting member may be disposed to be in contact with the insulating layer.

The cap may include a glass material, and the insulating layer may include at least one of silicon dioxide (SiO₂), silicon nitride (Si₃N₄), aluminum oxide (Al₂O₃), and aluminum nitride (AlN).

The bulk acoustic resonator package may include a support layer disposed between the substrate and the resonance portion; a membrane layer disposed between the support layer and the resonance portion and including a material that is different from a material included in the support layer; and an insulating layer disposed between the support layer and the substrate and including a material that is different from the material included in the support layer, wherein the cap melting member may be disposed to be in contact with the substrate.

The cap may include a glass material, and the substrate may include silicon (Si).

The bulk acoustic resonator package may further include an insulating bonding member disposed to surround the resonance portion, when viewed in the first direction, wherein the insulating bonding member may be disposed between the cap melting member and the substrate, and may be disposed to be in contact with the cap melting member.

The cap may include a glass material, and wherein the insulating bonding member may include at least one of silicon dioxide (SiO₂), silicon nitride (Si₃N₄), aluminum oxide (Al₂O₃), aluminum nitride (AlN), silicon (Si), and a piezoelectric material.

The resonance portion may further include at least one of an insertion layer and a passivation layer, wherein at least one of the insertion layer and the passivation layer may include at least one of silicon dioxide (SiO₂) and silicon nitride (Si₃N₄), and wherein the insulating bonding member may include at least one of silicon dioxide (SiO₂) and silicon nitride (Si₃N₄).

The cap melting member may include a material that is based on a melting of a material, different from glass, and glass.

The cap melting member may have a width of 35 μm or more to 50 μm or less.

A first portion of the surface of the cap facing the substrate may be configured to protrude toward the substrate further than a second portion of the cap facing the substrate.

The bulk acoustic resonator package may further include a hydrophobic layer disposed in at least one of between the resonance portion and the cap, and on a surface of the cap.

The bulk acoustic resonator package may further include a connection pattern configured to have at least a portion, that penetrates through the cap, and configured to electrically connect to at least one of the first electrode and the second electrode, and configured to have at least a portion in contact with the hydrophobic layer.

The bulk acoustic resonator package may further include a hydrophobic layer disposed on a surface opposing a surface facing the cap on the substrate; and a connection pattern, configured to have at least a portion that penetrates through the substrate, and is configured to electrically connect to at least one of the first electrode and the second electrode, and configured to have a portion in contact with the hydrophobic layer.

In a general aspect, a bulk acoustic resonator package includes a lower side component comprising at least one of silicon dioxide (SiO₂), silicon nitride (Si₃N₄), aluminum oxide (Al₂O₃), aluminum nitride (AlN), silicon (Si), and a piezoelectric material; a cap including a glass material; a resonance portion including a first electrode, a piezoelectric layer, and a second electrode, stacked in a first direction in which the lower side component and the cap face each other, and disposed between the lower side component and the cap, wherein the cap is configured to be welded to at least a portion of the lower side component.

The lower side component may include a substrate; a support layer disposed between the substrate and the resonance portion; an insulating layer disposed between the support layer and the substrate; and a membrane layer disposed between the support layer and the resonance portion.

The lower side component may further include an insulating bonding member configured to be welded to the cap between the membrane layer and the cap.

The bulk acoustic resonator package may further include a hydrophobic layer disposed in at least one of between the resonance portion and the cap, on a surface of the cap, and on a surface of the substrate.

Other features and aspects will be apparent from the following detailed description, the drawings, and the claims.

### BRIEF DESCRIPTION OF DRAWINGS

FIGS. 1A to 1D are diagrams illustrating an example bulk acoustic resonator package, in accordance with one or more embodiments.

FIGS. 2A to 2D are cross-sectional views illustrating various example structures of a cap melting member of an example bulk acoustic resonator package, in accordance with one or more embodiments.

FIGS. 3A and 3B are cross-sectional views illustrating an example structure in which an electrical connection path is added to an example bulk acoustic resonator package, in accordance with one or more embodiments.

FIG. 4 is a diagram illustrating an example molecular structure according to an example of a material of a hydrophobic layer according to a bulk acoustic resonator, in accordance with one or more embodiments.

FIGS. 5a and 5b are schematic diagrams illustrating molecular structures of a precursor which may be used as an adhesive layer of a hydrophobic layer, in accordance with one or more embodiments.

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided so that this disclosure will be thorough and complete, and will fully convey the scope of the disclosure to one of ordinary skill in the art.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The drawings may not be to scale, and the relative size, proportions, and depiction of elements in the drawings may be exaggerated for clarity, illustration, and convenience.

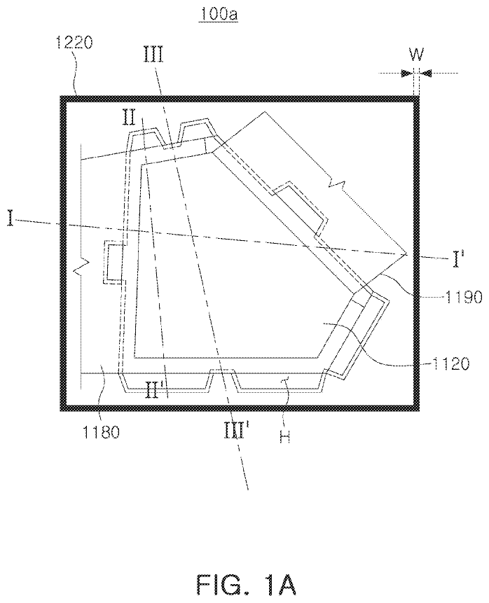

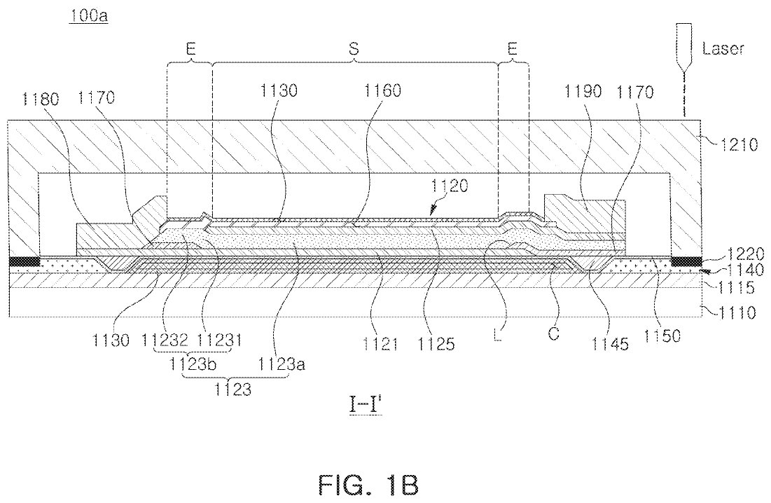

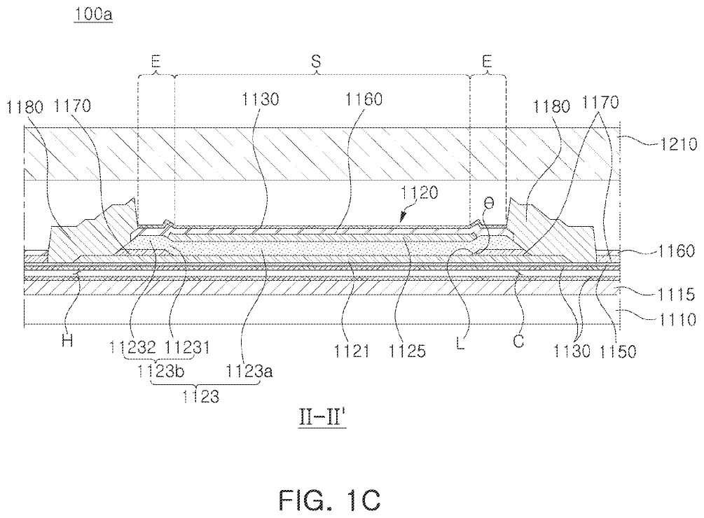

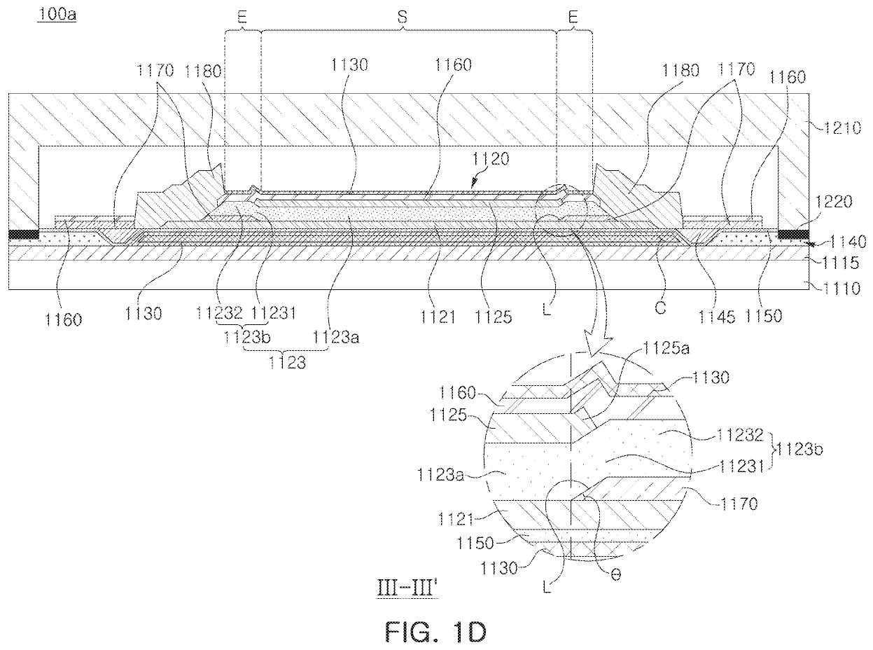

FIG. 1A is a plan view illustrating an example structure of an example bulk acoustic resonator which may be included in an example bulk acoustic resonator package, in accordance with one or more embodiments, FIG. 1B is a cross-sectional view taken along line I-I′ of FIG. 1A, FIG. 1C is a cross-sectional view taken along II-II′ of FIG. 1A, and FIG. 1D is a cross-sectional view taken along III-III′ of FIG. 1A.

Referring to FIGS. 1A to 1D, an example bulk acoustic resonator package 100a may include a support substrate 1110, an insulating layer 1115, a resonance portion 1120, and a hydrophobic layer 1130.

In an example, the support substrate 1110 may be a silicon substrate. In an example, a silicon wafer or a silicon-on-insulator (SOI) substrate may be implemented as the support substrate 1110.

The insulating layer 1115 may be provided on an upper surface of the support substrate 1110 to electrically isolate the support substrate 1110 from the resonance portion 1120. Additionally, the insulating layer 1115 may prevent the support substrate 1110 from being etched by an etching gas when the cavity C is formed during a method of manufacturing a bulk acoustic resonator.

In a non-limiting example, the insulating layer 1115 may be formed of at least one of silicon dioxide (SiO₂), silicon nitride (Si₃N₄), aluminum oxide (Al₂O₃), and aluminum nitride (AlN), and may be formed by at least one of processes such as, but not limited to, chemical vapor deposition, radio-frequency (RF) magnetron sputtering, and evaporation.

The support layer 1140 may be formed on the insulating layer 1115, and may be disposed around the cavity C and an etch-stop portion 1145 to surround the cavity C and the etch-stop portion 1145 therein.

The cavity C may be formed as an empty space, and may be formed by removing a portion of a sacrificial layer formed during preparation of the support layer 1140, and the support layer 1140 may be formed as a remaining portion of the sacrificial layer.

The support layer 1140 may be formed of a material, such as polysilicon, amorphous silicon, or the like, which may be easily etched. However, the material of the support layer 1140 is not limited thereto.

The etch-stop portion 1145 may be disposed along a boundary of the cavity C. The etch-stop portion 1145 may be provided to prevent etching from proceeding into the cavity region during formation of the cavity C.

A membrane layer 1150 may be formed on the support layer 1140, and may define an upper surface of the cavity C. Thus, the membrane layer 1150 may also be formed of a material which may not be easily removed during the formation of the cavity C.

In an example, when a halide-based etching gas such as fluorine (F), chlorine (Cl), or the like, is used to remove a portion of the support layer 1140 (for example, a cavity region), the membrane layer 1150 may be formed of a material having a low reactivity with the above-described etching gas. In this example, the membrane layer 1150 may include at least one of silicon dioxide (SiO₂) and silicon nitride (Si₃N₄).

Moreover, the membrane layer 1150 may include a dielectric layer including at least one of magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), and zinc oxide (ZnO), or may include a metal layer including at least one of aluminum (Al), nickel (Ni), chrome (Cr), platinum (Pt), gallium (Ga), or hafnium (Hf). However, the configuration of an example is not limited thereto.

The resonance portion 1120 may include a first electrode 1121, a piezoelectric layer 1123, and a second electrode 1125, which may be disposed sequentially. In the resonance portion 1120, the first electrode 1121, the piezoelectric layer 1123, and the second electrode 1125 may be stacked from below. Thus, in the resonance portion 1120, the piezoelectric layer 1123 may be disposed between the first electrode 1121 and the second electrode 1125.

The resonance portion 1120 may be formed on the membrane layer 1150, so that the membrane layer 1150, the first electrode 1121, the piezoelectric layer 1123, and the second electrode 1125 may be sequentially stacked to form the resonance portion 1120.

The resonance portion 1120 may resonate the piezoelectric layer 123 according to a signal, applied to the first electrode 1121 and the second electrode 1125, to generate a resonant frequency and an antiresonant frequency.

The resonance portion 1120 may be divided into a central portion S, in which the first electrode 1121, the piezoelectric layer 1123, and the second electrode 1125 are stacked in a substantially flat manner, and an extension portion E with an insertion layer 1170 interposed between the first electrode 1121 and the piezoelectric layer 1123.

The central portion S is a region disposed in the center of the resonance portion 1120, and the extension portion E is a region disposed along a periphery of the central portion S of the resonance portion 1120. Accordingly, the extension portion E is a region that extends outwardly from the central portion S, and refers to a region formed in a continuous annular shape along the periphery of the central portion S. However, as necessary, the extension portion E may be formed in a discontinuous annular shape in which some regions are cut.

Accordingly, as illustrated in FIG. 1B, in a cross-section in which the resonance portion 1120 is cut to cross the central portion S, extension portions E may be disposed on opposite ends of the central portion S, respectively. Additionally, insertion layers 1170 may be disposed on opposite sides of the extension portion E disposed on the opposite ends of the central portion S, respectively.

The insertion layer 1170 may have an inclined surface L having a thickness that is increased in a direction away from the central portion S.

In the extension portion E, the piezoelectric layer 1123 and the second electrode 1125 may be disposed on the insertion layer 1170. Accordingly, the piezoelectric layer 1123 and the second electrode 1125 disposed in the extension portion E may have inclined surfaces conforming to a shape of the insertion layer 1170.

The extension portion E may be defined as being included in the resonance portion 1120, so that resonance may also occur in the extension portion E. However, the one or more examples are not limited thereto. Depending on a structure of the extension portion E, resonance may not occur in the extension portion E, but resonance may occur only in the central portion S.

The first electrode 1121 and the second electrode 1125 may be formed of a conductive material, for example, gold, molybdenum, ruthenium, iridium, aluminum, platinum, titanium, tungsten, palladium, tantalum, chromium, nickel, or a metal including at least one thereof. However, the material of the first electrode 1121 and the second electrode 1125 is not limited thereto.

In a non-limiting example, first electrode 1121 may be formed to have a larger area than an area of the second electrode 1125 in the resonance portion 1120, and a first metal layer 1180 may be formed on at least a portion of the first electrode 1121 along an external periphery of the first electrode 1121. Accordingly, the first metal layer 1180 may be disposed to be spaced apart from the second electrode 1125 by a predetermined distance and to surround the resonance portion 1120.

Since the first electrode 1121 may be disposed on the membrane layer 1150, the first electrode 121 may be formed to be planar overall. On the other hand, since the second electrode 1125 may be disposed on the piezoelectric layer 1123, the second electrode 1125 may be bent to correspond to a shape of the piezoelectric layer 1123.

The first electrode 1121 may be implemented as either one of an input electrode and an output electrode that inputs and outputs an electrical signal such as a radio-frequency (RF) signal.

In a non-limiting example, the second electrode 1125 may be entirely disposed in the central portion S, and may be partially disposed in the extension portion E. The second electrode 1125 may be divided into a first portion, that is disposed on a piezoelectric portion 1123a of the piezoelectric layer 1123, and a second portion that is disposed on a bent portion 1123b of the piezoelectric layer 123.

In an example, the second electrode 1125 may be disposed to cover the entire piezoelectric portion 1123a and a portion of an inclined portion 11231 (FIG. 1D) of the piezoelectric layer 1123. Accordingly, a portion (1125a, FIG. 1D) of the second electrode 1125 disposed in the extension portion E, may be formed to have an area less than an area of an inclined surface of the inclined portion 11231 (FIG. 1D), and the second electrode 1125 in the resonance portion 1120 may be formed to have an area less than an area of the piezoelectric layer 123.

Accordingly, as illustrated in FIG. 1B, in a cross-section in which the resonance portion 1120 is cut to cross the central portion S, an end of the second electrode 1125 may be disposed in the extension portion E. Moreover, at least a portion of the end of the second electrode 125, disposed in the extension portion E, may be disposed to overlap the insertion layer 1170. The term “overlap” means that a shape of the second electrode 1125, projected onto a plane, overlaps the insertion layer 1170 when the second electrode 1125 is projected onto the plane on which the insertion layer 170 is disposed.

The second electrode 1125 may be implemented as either one of an input electrode and an output electrode that inputs and outputs an electrical signal such as a radio-frequency (RF) signal, or the like. In an example, when the first electrode 1121 is implemented as an input electrode, the second electrode 1125 may be implemented as an output electrode. Alternatively, when the first electrode 1121 is implemented as an output electrode, the second electrode 1125 may be implemented as an input electrode.

As illustrated in FIG. 1D, when an end of the second electrode 1125 is disposed on the inclined portion 11231 of the piezoelectric layer 1123 to be described later, a local structure of an acoustic impedance of the resonance portion 1120 may be formed in a sparse/dense/sparse/dense structure from the central portion S to increase a reflective interface reflecting a lateral wave inwardly of the resonance portion 1120. Therefore, most lateral waves may not flow outwardly of the resonance portion 1120 and may then be reflected to flow to an interior of the resonance portion 1120, so that performance of the acoustic resonator may be improved.

The piezoelectric layer 1123 may be a portion converting electrical energy into mechanical energy in a form of elastic waves through a piezoelectric effect, and may be formed on the first electrode 1121 and the insertion layer 1170 to be described later.

Zinc oxide (ZnO), aluminum nitride (AlN), doped aluminum nitride, lead zirconate titanate, quartz, and the like may be selectively used as a material of the piezoelectric layer 123. In the case of doped aluminum nitride, a rare earth metal, a transition metal, or an alkaline earth metal may be further included. The rare earth metal may include at least one of scandium (Sc), erbium (Er), yttrium (Y), and lanthanum (La). The transition metal may include at least one of hafnium (Hf), titanium (Ti), zirconium (Zr), tantalum (Ta), and niobium (Nb). In addition, the alkaline earth metal may include magnesium (Mg). The content of elements doped into aluminum nitride (AlN) may be in a range of 0.1 to 30 at %.

The piezoelectric layer 1123 may be used by doping aluminum nitride (AlN) with scandium (Sc). In this example, a piezoelectric constant may be increased to increase Kt2 of the bulk acoustic resonator.

The piezoelectric layer 1123 may include a piezoelectric portion 1123a, disposed in the central portion S, and a bent or inclined portion 1123b disposed in the extension portion E.

The piezoelectric portion 1123a may be a portion directly stacked on an upper surface of the first electrode 1121. Accordingly, the piezoelectric portion 1123a may be interposed between the first electrode 1121 and the second electrode 1125 to be formed in a flat shape, together with the first electrode 1121 and the second electrode 1125.

The bent portion 1123b may be defined as a region that extends outwardly from the piezoelectric portion 1123a, and disposed in the extension portion E.

The bent portion 1123b may be disposed on the insertion layer 1170 to be described later, and may be formed in a shape in which an upper surface thereof is raised along a shape of the insertion layer 1170. Accordingly, the piezoelectric layer 1123 may be curved or bent on a boundary between the piezoelectric portion 1123a and the bent portion 1123b, and the bent portion 1123b may be raised to correspond to a thickness and the shape of the insertion layer 170.

The bent portion 1123b may be divided into an inclined portion 11231 and an extension portion 11232.

The inclined portion 11231 may be a portion that is formed to be inclined along an inclined surface L of the insertion layer 1770 to be described later. The extension portion 11232 may be a portion that extends outwardly from the inclined portion 11231.

The inclined portion 11231 may be formed to be parallel to the inclined surface L of the insertion layer 1170, and an angle of inclination of the inclined portion 11231 may be the same as an angle of inclination of the inclined surface L of the insertion layer 1170.

The insertion layer 1170 may be disposed along a surface formed by the membrane layer 1150, the first electrode 1121, and the etch stop portion 1145. Accordingly, the insertion layer 1170 may be partially disposed in the resonance portion 1120, and may be disposed between the first electrode 1121 and the piezoelectric layer 1123.

The insertion layer 1170 may be disposed around the central portion S to support the bent portion 1123b of the piezoelectric layer 1123. Accordingly, the bent portion 1123b of the piezoelectric layer 1123 may be divided into the inclined portion 11231 and the extension portion 11232 disposed along the shape of the insertion layer 170.

In an example, the insertion layer 1170 may be disposed in a region, other than the central portion S. In one or more examples, the insertion layer 1170 may be disposed on the substrate 1110 in an entire region, other than the central portion S, on the support substrate 1110, or may be disposed in some regions, other than the central portion S, on the support substrate 1110.

The insertion layer 1170 may be formed to have a thickness that increases in a direction that extends from the central portion S. Thus, the insertion layer 1170 may be formed to have a side surface, disposed adjacent to the central portion S, including an inclined surface L having a predetermined inclination angle θ. In an example, the predetermined inclination angle θ may be formed to be 5 degrees or more to 70 degrees or less.

The inclined portion 11231 of the piezoelectric layer 1123 may be formed along the inclined surface L of the insertion layer 1170, and thus may be formed at the same inclination angle as the inclined surface L of the insertion layer 1170. Accordingly, the inclination angle of the inclined portion 11231 may also be formed to be 5 degrees or more to 70 degrees or less, similarly to the inclined surface L of the insertion layer 1170. Such a configuration may also be equally applied to the portion of the second electrode 1125 stacked on the inclined surface L of the insertion layer 1170.

In a non-limited example, the insertion layer 1170 may be formed of a dielectric material such as silicon oxide (SiO₂), aluminum nitride (AlN), aluminum oxide (Al₂O₃), silicon nitride (Si₃N₄), magnesium oxide (MgO), zirconium oxide (ZrO₂), lead zirconate titanate (PZT), gallium arsenic (GaAs), hafnium oxide (HfO2), titanium oxide (TiO2), zinc oxide (ZnO), or the like, but may be formed of a material different from that of the piezoelectric layer 1123.

Additionally, the insertion layer 1170 may be implemented with a metal material. When the acoustic wave resonator 100 is used for 5G communications, a large amount of heat may be generated by the resonance portion 1120, and thus, the heat generated by the resonance portion 1120 should be smoothly released. Accordingly, in an example, the insertion layer 1170 may be formed of an aluminum alloy material containing scandium (Sc).

The resonance portion 1120 may be disposed to be spaced apart from the substrate 1110 through a cavity C formed as an empty space.

The cavity C may be formed by removing a portion of a sacrificial layer 1140 by supplying an etching gas (or an etching solution) to an inlet hole (H of FIG. 1) in a process of manufacturing the bulk acoustic resonator.

Accordingly, the cavity C is a space having an upper surface (a ceiling surface) and a side surface (a wall surface), defined by the membrane layer 1150, and a bottom surface defined by the support substrate 1110 or the insulating layer 1115. In an example, the membrane layer 1150 may be formed only on the upper surface (the ceiling surface) of the cavity C according to the order of the manufacturing method.

A passivation layer or protection layer 1160 may be disposed along a surface of the acoustic resonator package 100a to protect the acoustic resonator package 100a from the external environment. The passivation layer 1160 may be disposed along a surface defined by the second electrode 1125 and the bent portion 1123b of the piezoelectric layer 1123.

The passivation layer 1160 may be partially removed for frequency control in a final process of the manufacturing method. In an example, a thickness of the passivation layer 1160 may be adjusted through frequency trimming in the manufacturing method.

In a non-limiting example, the passivation layer 1160 may include one of silicon oxide (SiO₂), silicon nitride (Si₃N₄), manganese oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), zinc oxide (ZnO), amorphous silicon (a-Si), polycrystalline silicon (p-Si), but the material of the passivation layer 1160 is not limited thereto.

The first electrode 1121 and the second electrode 1125 may extend outwardly of the resonance portion 1120. Additionally, a first metal layer 1180 and a second metal layer 1190 may each be disposed on an upper surface of the extended portion of the resonance portion 1120.

In a non-limiting example, the first metal layer 1180 and the second metal layer 1190 may be formed of one of gold (Au), a gold-tin (Au—Sn) alloy, copper (Cu), a copper-tin (Cu—Sn) alloy, aluminum (Al), and an aluminum alloy. The aluminum alloy may be an aluminum-germanium (Al—Ge) alloy or an aluminum-scandium (Al—Sc) alloy.

The first metal layer 1180 and the second metal layer 1190 may be implemented as an interconnection line, that electrically connects the electrodes 1121 and 1125 of the bulk acoustic resonator to an electrode of an adjacent bulk acoustic resonator, on the support substrate 1110.

At least a portion of the first metal layer 1180 may be in contact with the passivation layer 1160 and may be bonded to the first electrode 1121.

In the resonance portion 1120, the first electrode 1121 may be formed to have an area larger than an area of the second electrode 1125, and the first metal layer 1180 may be formed on a peripheral portion of the first electrode 1121.

Accordingly, the first metal layer 1180 may be disposed along the periphery of the resonance portion 1120, and may be disposed to surround the second electrode 1125. However, the examples are not limited thereto.

In the bulk acoustic resonator, a hydrophobic layer 1130 may be disposed on a surface of the passivation layer 1160 and an internal wall of the cavity C. The hydrophobic layer 1130 may suppress adsorption of water and a hydroxyl group (OH group) to significantly reduce frequency variations, so that resonator performance may be maintained to be uniform.

The hydrophobic layer 1130 may be formed of a self-assembled monolayer (SAM) forming material, rather than a polymer. When the hydrophobic layer 1130 is formed of a polymer, mass due to the polymer may affect the resonance portion 1120. However, since the hydrophobic layer 1130 may be formed of a self-assembled monolayer in the acoustic resonator according to an example, a change in frequency of an acoustic resonator may be significantly reduced. Additionally, a thickness of the hydrophobic layer 1130, depending on a position in the cavity C, may be uniform.

The hydrophobic layer 1130 may be formed by vapor deposition of a precursor which may have hydrophobicity. In this example, the hydrophobic layer 1130 may be deposited as a monolayer having a thickness of 100 angstroms or less (in an example, several angstroms to several tens of angstroms). The precursor, which may have hydrophobicity, may be formed with a material in which a contact angle with water is 90 degrees or more after deposition. In an example, the hydrophobic layer 1130 may contain a fluorine (F) component, and may include fluorine (F) and silicon (Si). In an example, fluorocarbon having a silicon head may be used, but the examples are not limited thereto.

To improve adhesion between the self-assembled monolayer, forming the hydrophobic layer 1130, and the passivation layer 1160, an adhesion layer (not illustrated) may be formed on the passivation layer 1160 may be formed before the hydrophobic layer 1130 is formed.

The adhesion layer may be formed by vapor-depositing a precursor having a hydrophobic functional group on a surface of the passivation layer 1160.

The precursor, used for deposition of the adhesion layer, may be hydrocarbon having a silicon head or siloxane having a silicon head.

The hydrophobic layer 1130 may be formed after the first metal layer 1180 and the second metal layer 1190 are formed, and thus may be formed along surfaces of the passivation layer 1160, the first metal layer 1180, and the second metal layer 1190.

The drawings illustrate the example in which the hydrophobic layer 1130 is not disposed on surfaces of the first metal layer 1180 and the second metal layer 1190, but the examples are not limited thereto. As necessary, the hydrophobic layer 1130 may also be disposed on the surfaces of the first metal layer 1180 and the second metal layer 1190.

Moreover, the hydrophobic layer 1130 may be disposed on not only an upper surface of the passivation layer 1160, but also an internal surface of the cavity C.

The hydrophobic layer 1130, formed in the cavity C, may be formed in the entirety of an internal wall forming the cavity C. Accordingly, the hydrophobic layer 1130 may also be formed on a lower surface of the membrane layer 1150 forming a lower surface of the resonance portion 1120. In this example, adsorption of a hydroxyl group to a lower portion of the resonance portion 1120 may be suppressed.

The adsorption of the hydroxyl group occurs, not only in the passivation layer 1160, but also in the cavity C. Thus, to significantly reduce mass loading, caused by adsorption of the hydroxyl group, and frequency drop thereby, the adsorption of the hydroxyl group may be blocked in the passivation 1160, as well as on an upper surface of the cavity C (a lower surface of a membrane layer 1150), for example, a lower surface of the resonance portion.

Additionally, when the hydrophobic layer 1130 is formed on an upper surface and a lower surface or a side surface of the cavity C, an effect of suppressing the occurrence of stiction, a phenomenon in which the resonance portion 1120 is adhered to the insulating layer 1115 due to surface tension in a wetting process or a cleaning process after formation of the cavity C, may be provided.

An example, in which the hydrophobic layer 1130 is formed in the entirety of an internal wall of the cavity C, has been described, but the examples are not limited thereto. Alternatively, various modifications may be made. In an example, the hydrophobic layer 1130 may only be formed on an upper surface of the cavity C, or the hydrophobic layer 1130 may only be formed in at least a portion of a lower surface and a side surface of the cavity C.

Referring to FIGS. 1A and 1B, the bulk acoustic resonator package 100a according to an example may include a substrate 1110, a cap 1210, a resonance portion 1120, and a cap melting member 1220.

The resonance portion 1120 may include a first electrode 1121, a piezoelectric layer 1123, and a second electrode 1125 sequentially stacked in one direction (for example, a vertical direction) in which the substrate 1110 and the cap 1210 face each other, and may be accommodated between the substrate 1110 and the cap 1210.

The cap 1210 may accommodate the resonance portion 1120 to protect the resonance portion 1120 from an external environment. The cap 1210 may be formed in a form of a cover having an internal space in which the resonance portion 1120 is accommodated. In an example, in the cap 1210, a portion of the surface (for example, a lower surface) facing the substrate 1110 (for example, a portion adjacent to an edge of the lower surface) may protrude further than another portion (for example, a center of the lower surface) toward the substrate 1110. In an example, the cap 1210 may have a U-shape when viewed in a horizontal direction.

When viewed in one direction (for example, the vertical direction) (for example, when viewed in FIG. 1A), the cap melting member 1220 may be disposed to surround the resonance portion 1120 and to be in contact with a portion of a surface of the cap 1210 (for example, a lower surface of the cap 1210) facing the substrate 1110 (for example, a portion adjacent to an edge of the lower surface), and may include a material or a structure based on melting of a portion of the surface of the cap 1210. In an example, the cap melting member 1220 may be formed by welding the cap 1210 to at least a portion of a lower side component (for example, at least one of the support layer 1140, the membrane layer 1150, the insulating layer 1115, and the substrate 1110) of the cap 1210.

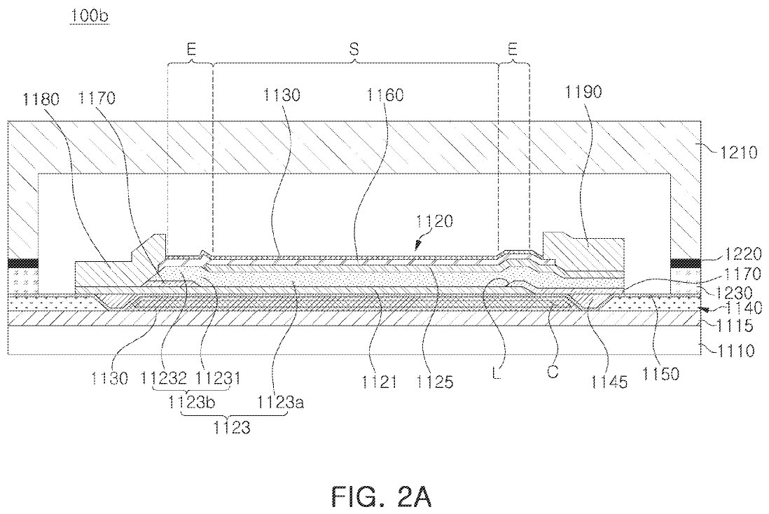

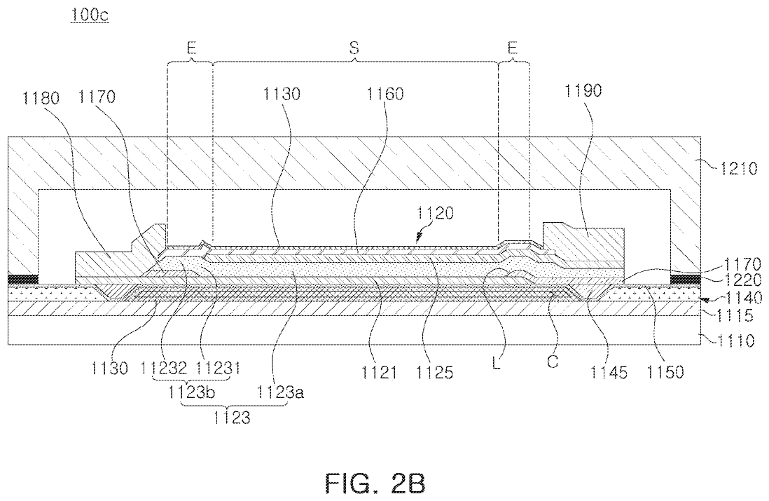

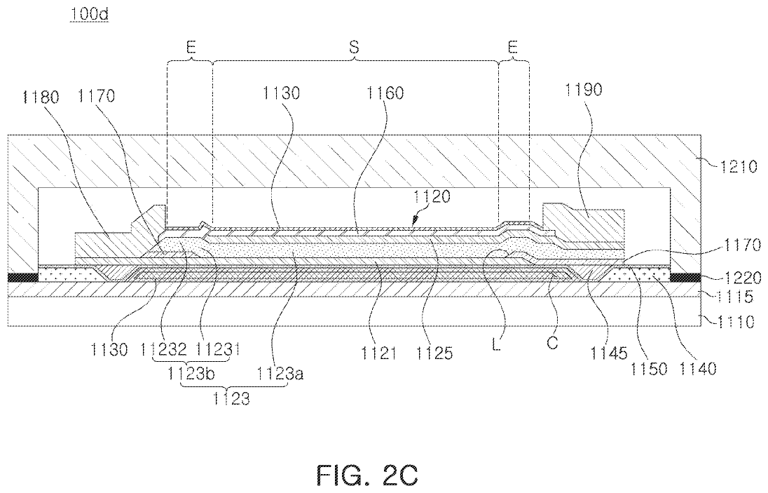

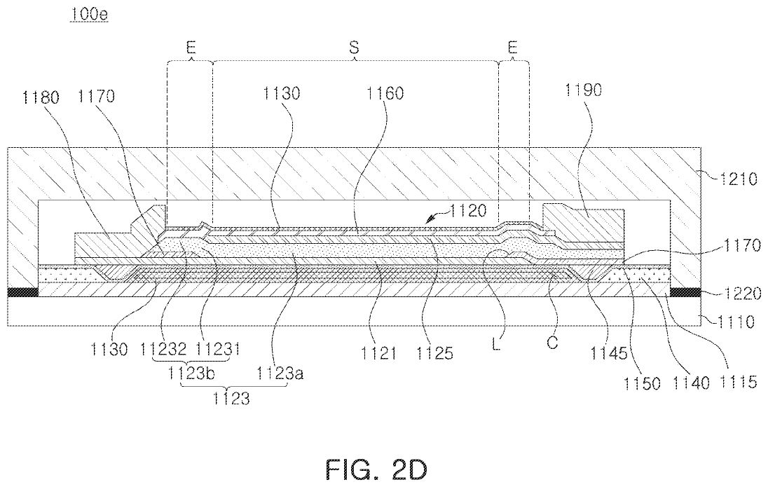

Accordingly, the cap 1210 may be bonded to the component (for example, at least one of the support layer 1140, the membrane layer 1150, the insulating layer 1115, and the substrate 1110) on the lower side of the cap 1210, and may be bonded to the component on the lower side of the cap 1210 without an additional bonding structure (for example, eutectic bonding, anodic bonding, or the like). Alternatively, the cap 1210 may be bonded to the component on the lower side of the cap 1210 through patterning in the form of allowing a portion of the piezoelectric layer 1123 to remain between the component on the lower side of the cap 1210 and the cap 1210. The portion of the piezoelectric layer 1123 may correspond to the insulating bonding member 1230 illustrated in FIG. 2A, and the insulating bonding member 1230 may be configured as a portion of the lower side component of the cap 1210.

As described above, since the additional bonding structure may be omitted, the bulk acoustic resonator package 100a according to an example may be advantageously implemented to have a smaller size (for example, a relatively small width of the cap melting member 1220, a height reduced by a height of the additional bonding structure, or the like), may be advantageously implemented with lower costs, and may reduce a probability that unwanted parasitic inductance/capacitance of the resonance portion 1120 (for example, mutual inductance generated as the additional bonding structure acts as an adjacent wire) will be generated. Furthermore, since the above advantages of the bulk acoustic resonator package 100a may be more beneficial in the technological trend for a decrease in wavelength of a radio-frequency signal passing through a bulk acoustic resonator, the bulk acoustic resonator package 100a according to an example may efficiently increase or widen a frequency band of a bulk acoustic resonator filter, may be advantageous to form a frequency band to be closer to an adjacent communications band, and may be advantageous in reducing energy loss within a frequency band.

In an example, a width W of the cap melting member 1220 may be 35 μm or more to 50 μm or less (for example, 35.7 μm, 42.9 μm, 46.4 μm, 50.0 μm), and thus may be less than a width of the additional bonding structure (for example, eutectic bonding, anodic bonding, or the like) (for example, 80 um to 100 um). In an example, it may be beneficial that the additional bonding structure have an effective bonding area for the bulk acoustic resonator package in consideration of unnecessary parasitic inductance/capacitance of the resonance portion 1120, but the bulk acoustic resonator package according to an example may be advantageously implemented to have a smaller size because the effective bonding area may not have to be taken into account. In an example, the width W of the cap melting member 1220 may be measured by analysis using at least one of a transmission electron microscopy (TEM), an atomic force microscope (AFM), a scanning electron microscope (SEM), an optical microscope, and a surface profiler. Not only the width of the cap melting member 1220, but also other dimensions of the bulk acoustic resonator package according to an example may be measured by analysis using at least one of a TEM, an AFM, a SEM, an optical microscope, and a surface profiler.

In an example, the cap melting member 1220 may be formed by continuously irradiating a laser to a portion of a surface (for example, a lower surface) facing the substrate 1110 in the cap 1210 (for example, a portion adjacent to an edge of the lower surface).

The cap 1210 may be temporarily bonded to the lower side component (for example, at least one of the support layer 1140, the membrane layer 1150, the insulating layer 1115, and the substrate 1110) before laser is irradiated to the cap 1210. In an example, an adhesive and/or a jig may be implemented to temporary bond the cap 1210. In an example, the cap 1210 and the lower side component may be aligned with each other on a wafer level to be temporarily bonded to each other, and the laser may be vertically irradiated from an upper side of the temporarily bonded structure. In an example, the cap 1210 may have a shape accommodating each of a plurality of bulk acoustic resonators, and may be cut by a dicing process after being bonded to the lower side component. In an example, the plurality of bulk acoustic resonator packages may be simultaneously manufactured.

Conditions of a boundary between the cap 1210 and the lower side component, bonded to each other, may cause an energy absorption phenomenon based on a wavelength of irradiated laser, and an increase in temperature depending on the energy absorption phenomenon of the conditions of the boundary may cause a portion of the cap 1210 to be melted, and the cap melting member 1220 formed by melting the portion of the cap 1210 may have a structure and/or a material depending on welding between the cap 1210 and the lower side component.

Therefore, a material of the lower side component welded to the cap 1210 is not limited as long as it can cause an energy absorption phenomenon based on a wavelength of irradiated laser. In an example, the material of the lower side component may include the same material as the material included in at least one of the support layer 1140, the membrane layer 1150, the insulating layer 1115, and the substrate 1110, and may include the same material as a piezoelectric material of the piezoelectric layer 1123. In an example, the cap 1210 may be bonded to the lower side component through patterning by allowing a portion of the piezoelectric layer 1123 to remain between the lower side component and the cap 1210. Since a wavelength, power, focusing position, and the like, of the laser may be adjusted and may affect formation of the cap melting member 1220, a selectable range of the material for the lower side component welded to the cap 1210 may be wide and relatively free.

Accordingly, the cap melting member 1220 may include a material other than glass (for example, silicon dioxide (SiO₂), silicon nitride (Si₃N₄), aluminum oxide (Al₂O₃), and aluminum nitride (AlN), silicon (Si), polysilicon (poly-Si), aluminum scandium nitride (AlScN)) and a material based on the melting of glass.

A direction of irradiation the laser is not limited. In an example, at least a portion of the cap 1210 may be sufficiently transparent to allow a laser to pass therethrough, and the laser may be irradiated to pass through the cap 1210 from an upper side to a lower side of the cap 1210. Accordingly, the focusing position of the laser may be more precisely controlled.

Referring to FIG. 1A, the cap melting member 1220 is illustrated as surrounding a single resonance portion 1120. However, the number of resonance portions 1120 surrounded by the cap melting member 1220 may be two or more. In an example, a plurality of resonators 1120 may be a plurality of bulk acoustic resonators, and a plurality of bulk acoustic resonators may be implemented as a bulk acoustic resonator filter. In an example, the bulk acoustic resonator filter may have a structure in which a plurality of bulk acoustic resonators are connected in ladder form and/or lattice form, and may be implemented such that a plurality of (anti)resonant frequencies of the plurality of bulk acoustic resonators are different from each other. The plurality of (anti)resonant frequencies may be determined by a horizontal area (for example, a square of 70 μm) of the resonance portion 1120 or a thickness or a frame and/or a width of at least a portion (for example, electrode) of the resonance portion 1120. The horizontal area refers to an area in which the first electrode 1121, the piezoelectric layer 1123, and the second electrode 1125 overlap each other in a vertical direction.

Referring to FIGS. 1A to 1D, the support layer 1140 disposed between the substrate 1110 and the resonance portion 1120 may be disposed to be in contact with the cap melting member 1220. FIGS. 1B to 1D illustrate a structure in which the support layer 1140 provides the cavity C, but the cavity C may be omitted. In an example, the bulk acoustic resonator package according to an example may be implemented in solidly mounted resonator (SMR) form. The bulk acoustic resonator package, implemented in SMR form, may have a structure in which a plurality of metal layers and a plurality of insulating layers are alternately stacked to provide a specific acoustic impedance boundary condition, instead of the cavity C.

In an example, the support layer 1140 may have a stepped portion to provide a space in which the cap melting member 1220 is disposed. Accordingly, at least a portion of the cap melting member 1220 may be in close contact with a portion of the support layer 1140. Accordingly, a horizontal position of the cap 1210 may be more precisely adjusted, and a focusing position of the laser may be more precisely controlled.

In an example, the cap 1210 may include glass, and the support layer 1140 may include at least one of polysilicon and amorphous silicon. Since the support layer 1140 including at least one of polysilicon and amorphous silicon may have substantially no cracking occurring in a surface thereof in a process of forming (or welding) the cap molten member 1220, the support layer 1140 may be efficiently bonded to the cap 1210 through the cap melting member 1220. In an example, the cap melting member 1220 may be formed to have a width W of 46.4 μm, but a width of the cap melting member 1220 is not limited thereto. The support layer 1140 may include a material different from the material included in the membrane layer 1150, and may include a material different from the material included in the insulating layer 1115.

FIGS. 2A to 2D are cross-sectional views illustrating various structures of a cap melting member of a bulk acoustic resonator package, in accordance with one or more embodiments.

Referring to FIG. 2A, a bulk acoustic resonator package 100b, in accordance with one or more embodiments, may further include an insulating bonding member 1230 disposed to surround a resonance portion 1120, and to be in contact with a cap melting member 1220 between the cap melting member 1220 and a substrate 1110, when viewed in one direction (for example, a vertical direction).

In an example, the insulating bonding member 1230 may include a material further optimized for laser welding, may be used to adjust a height of the bulk acoustic resonator package 100b, and may have a structure adaptive to another type of the cap 1210 (for example, a shape having no portion protruding to an edge).

In an example, the insulating bonding member 1230 may include at least one of silicon dioxide (SiO₂), silicon nitride (Si₃N₄), aluminum oxide (Al₂O₃), aluminum nitride (AlN), silicon (Si), and a piezoelectric material.

In an example, the insulating bonding member 1230 may include the same piezoelectric material as the piezoelectric material of the piezoelectric layer 1123. Accordingly, the insulating bonding member 1230 may be advantageous if formed at the same time as the piezoelectric layer 1123, so that process efficiency of the bulk acoustic resonator package 100b may be improved. The insulating bonding member 1230 including a piezoelectric material (for example, aluminum nitride (AlN), aluminum scandium nitride (AlScN), or the like) may rarely have cracking occurring in the surface thereof in the formation process (or welding process) of the cap melting member 1220, and thus may be bonded to the cap 1210 through the cap melting member 1220. In an example, the cap melting member 1220 may be formed to have a width of 50.0 μm (corresponding to AlN) or 42.9 μm (corresponding to AlScN), but a width of the cap melting member 1220 is not limited thereto.

Referring to FIG. 2B, a cap melting member 1220 of a bulk acoustic resonator package 100c in accordance with one or more embodiments, may be disposed to be in contact with a membrane layer 1150. In an example, the membrane layer 1150 may include at least one of silicon dioxide (SiO₂) and silicon nitride (Si₃N₄). The membrane layer 1150 including at least one of silicon dioxide (SiO₂) and silicon nitride (Si₃N₄) may have substantially no cracking occurring in a surface thereof in a process of forming (or welding) a cap melting member 1220, and thus may be efficiently bonded to the cap 1210 through the cap melting member 1220. In an example, the cap melting member 1220 may be formed to have a width of 35.7 μm, but a width of the cap melting member 1220 is not limited thereto.

Referring to FIG. 2C, a cap melting member 1220 of a bulk acoustic resonator package 100d, in accordance with one or more embodiments, may be disposed to be in contact with an insulating layer 1115. In an example, the insulating layer 1115 may include at least one of silicon dioxide (SiO₂), silicon nitride (Si₃N₄), aluminum oxide (Al₂O₃), and aluminum nitride (AlN), as non-limiting examples.

Referring to FIG. 2D, a cap melting member 1220 of a bulk acoustic resonator package 100e, in accordance with one or more embodiments may be disposed to be in contact with a substrate 1110.

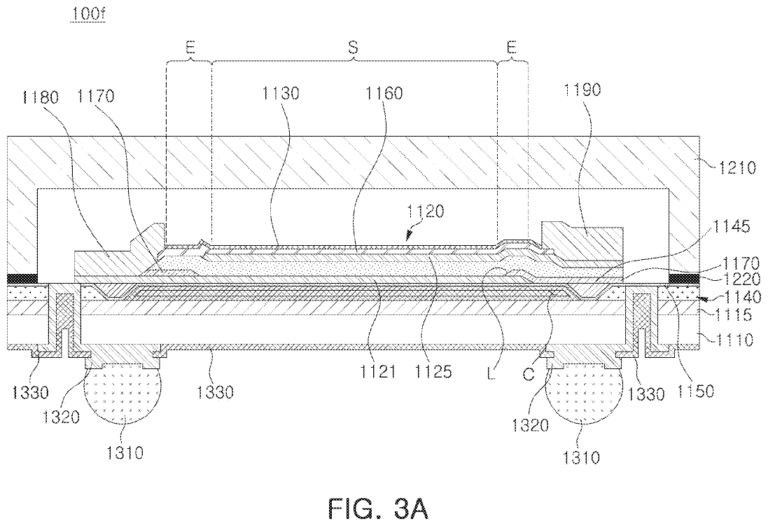

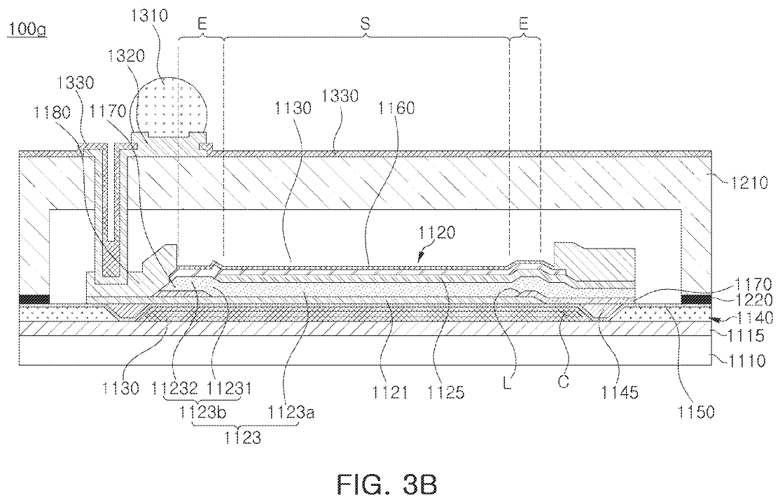

FIGS. 3A and 3B are cross-sectional views illustrating an example structure in which an electrical connection path is added to an example bulk acoustic resonator package, in accordance with one or more embodiments.

Referring to FIGS. 3A and 3B, bulk acoustic resonator packages 100f and 100g, in accordance with one or more embodiments, may further include at least one of a hydrophobic layer 1130, a bump 1310, a connection pattern 1320, and a hydrophobic layer 1330.

The hydrophobic layer 1130 may be disposed between the resonance portion 1120 and the cap 1210, and may be more hydrophobic than the cap 1210. Accordingly, adsorption of organic substances, moisture, or the like, which may be generated in a process of forming the cap melting member 1220, to the resonance portion 1120 may be reduced, so that characteristics of the resonance portion 1120 may be further improved. In an example, a hydrophobic layer 1130 may be formed on an upper surface of the resonance portion 1120.

Referring to FIG. 3A, at least a portion of the connection pattern 1320 may penetrate through a substrate 1110, may be electrically connected to at least one of the respective first and second electrodes 1121 and 1125, and may be in contact with the hydrophobic layer 1330. Accordingly, the resonance portion 1120 may be electrically connected to an external entity of the bulk acoustic resonator package 100f.

The hydrophobic layer 1330 may be disposed on a surface (for example, a lower surface) opposing a surface (for example, an upper surface) facing the cap 1210 on the substrate 1110, and may be relatively more hydrophobic than the substrate 1110. Accordingly, adsorption of organic substances, moisture, or the like, which may be generated in a process of forming the cap melting member 1220, to the connection pattern 1320 may be reduced, so that transmission loss in the connection pattern 1320 may be further reduced.

Referring to FIG. 3B, at least a portion of the connection pattern 1320 may penetrate through the cap 1210, may be electrically connected to at least one of the respective first and second electrodes 1121 and 1125, and may be in contact with the hydrophobic layer 1330. Accordingly, the resonance portion 1120 may be electrically connected to an external entity of the bulk acoustic resonator package 100g.

The hydrophobic layer 1330 may be disposed on a surface (for example, an upper surface) opposing a surface (for example, a lower surface) facing the substrate 1110 in the cap 1210, and may be relatively more hydrophobic than the cap 1210. Accordingly, adsorption of organic substances, moisture, or the like, which may be generated in a process of forming the cap melting member 1220, to the connection pattern 1320, may be reduced, so that transmission loss in the connection pattern 1320 may be further reduced.

In an example, in a state in which there is a hole in a portion of the substrate 1110 and/or the cap 1210, the connection pattern 1320 may be formed through a process of depositing, applying, or filling a conductive metal (for example, gold, copper, titanium-copper (Ti—Cu) alloy, or the like) on a sidewall of the hole.

On the other hand, a process of forming a hole in a portion of the substrate 1110 and/or the cap 1210 may be omitted. In an example, the resonance portion 1120 may receive an electrical connection path through wire bonding.

The bump 1310 may have a structure supporting bulk acoustic resonator packages 100f and 100g such that the bulk acoustic resonator packages 100f and 100g may be mounted on an external printed circuit board (PCB) on a lower side thereof. In an example, a portion of the connection pattern 1320 may have a pad shape in contact with the bump 1310.

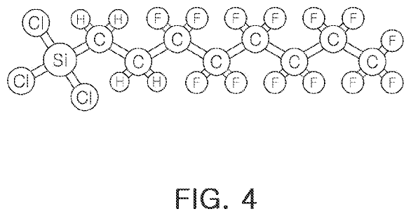

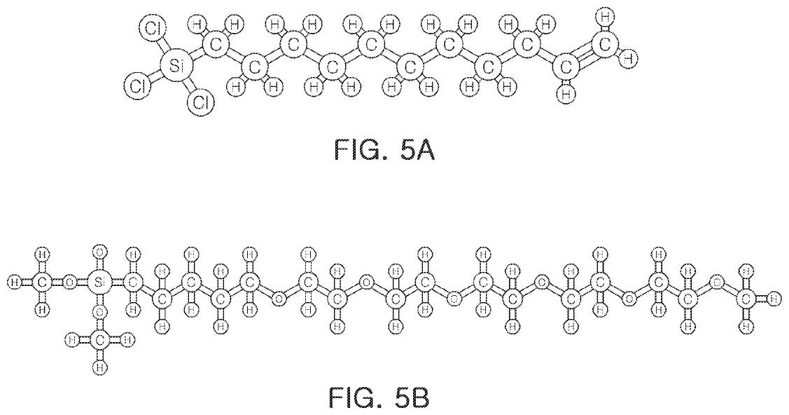

FIG. 4 is a diagram illustrating an example molecular structure according to an example of a material of a hydrophobic layer according to a bulk acoustic resonator package, in accordance with one or more embodiments, and FIGS. 5A and 5B are schematic diagrams illustrating molecular structures of a precursor which may be used as an adhesive layer of a hydrophobic layer.

Referring to FIG. 4, a hydrophobic layer may include a hydrophobic material having a fluorocarbon group. In an example, the hydrophobic material having a fluorocarbon group may be a material of which a contact angle by water is 90 degrees or more after being deposited, and may include fluorine (F) and silicon (Si).

Referring to FIG. 5A, a precursor may be hydrocarbon having a silicon head. Referring to FIG. 5B, a precursor may be siloxane having a silicon head.

As described above, an example bulk acoustic resonator package, in accordance with one or more embodiments, may be advantageously implemented with lower costs, and/or may reduce a probability that unwanted parasitic inductance/capacitance of the resonance portion 1120 will be generated. Furthermore, since the above advantages of the bulk acoustic resonator package may be more beneficial in the technological trend for a decrease in wavelength of a radio-frequency signal passing through a bulk acoustic resonator, the bulk acoustic resonator package according to an example may efficiently increase or widen a frequency band of a bulk acoustic resonator filter, may be advantageous for forming a frequency band to be closer to an adjacent communications band, and/or may be advantageous for reducing energy loss within a frequency band.

While specific examples have been illustrated and described above, it will be apparent after gaining an understanding of this disclosure that various changes in form and details may be made in these examples without departing from the spirit and scope of the claims and their equivalents. The examples described herein are to be considered in a descriptive sense only, and are not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic resonator package, comprising:
a substrate;
a cap;
a resonance portion comprising a first electrode, a piezoelectric layer, and a second electrode, stacked in a first direction in which the substrate and the cap face each other, and disposed between the substrate and the cap; and
a cap melting member disposed to surround the resonance portion, and disposed to be in contact with a portion of a surface of the cap facing the substrate, when viewed in the first direction, and comprising a material or a structure that is based on a melting of the portion of the surface of the cap.

2. The bulk acoustic resonator package of claim 1, further comprising:
a support layer disposed between the substrate and the resonance portion,
wherein the cap melting member is disposed to be in contact with the support layer.

3. The bulk acoustic resonator package of claim 2, wherein the support layer is configured to provide a cavity that is disposed to be surrounded by the support layer, and
at least a portion of the resonance portion overlaps the cavity, when viewed in the first direction.

4. The bulk acoustic resonator package of claim 2, wherein the support layer is configured to have a stepped form that provides a space in which the cap melting member is disposed.

5. The bulk acoustic resonator package of claim 2, wherein the cap comprises a glass material, and
wherein the support layer comprises at least one of polysilicon and amorphous silicon.

6. The bulk acoustic resonator package of claim 1, further comprising:
a support layer disposed between the substrate and the resonance portion; and
a membrane layer disposed between the support layer and the resonance portion and comprising a material that is different from a material comprised in the support layer,
wherein the cap melting member is disposed to be in contact with the membrane layer.

7. The bulk acoustic resonator package of claim 6, wherein the cap comprises a glass material, and
wherein the membrane layer comprises at least one of silicon dioxide (SiO₂) and silicon nitride (Si₃N₄).

8. The bulk acoustic resonator package of claim 1, further comprising:
a support layer disposed between the substrate and the resonance portion; and
an insulating layer disposed between the support layer and the substrate, and comprising a material that is different from a material comprised in the support layer,
wherein the cap melting member is disposed to be in contact with the insulating layer.

9. The bulk acoustic resonator package of claim 8, wherein the cap comprises a glass material, and
the insulating layer comprises at least one of silicon dioxide (SiO₂), silicon nitride (Si₃N₄), aluminum oxide (Al₂O₃), and aluminum nitride (AlN).

10. The bulk acoustic resonator package of claim 1, further comprising:
a support layer disposed between the substrate and the resonance portion;
a membrane layer disposed between the support layer and the resonance portion and comprising a material that is different from a material comprised in the support layer; and
an insulating layer disposed between the support layer and the substrate and comprising a material that is different from the material comprised in the support layer,
wherein the cap melting member is disposed to be in contact with the substrate.

11. The bulk acoustic resonator package of claim 10, wherein the cap comprises a glass material, and
the substrate comprises silicon (Si).

12. The bulk acoustic resonator package of claim 1, further comprising:
an insulating bonding member disposed to surround the resonance portion, when viewed in the first direction,
wherein the insulating bonding member is disposed between the cap melting member and the substrate, and is disposed to be in contact with the cap melting member.

13. The bulk acoustic resonator package of claim 12, wherein the cap comprises a glass material, and
wherein the insulating bonding member comprises at least one of silicon dioxide (SiO₂), silicon nitride (Si₃N₄), aluminum oxide (Al₂O₃), aluminum nitride (AlN), silicon (Si), and a piezoelectric material.

14. The bulk acoustic resonator package of claim 12, wherein the resonance portion further comprises at least one of an insertion layer and a passivation layer,
wherein at least one of the insertion layer and the passivation layer comprises at least one of silicon dioxide (SiO₂) and silicon nitride (Si₃N₄), and
wherein the insulating bonding member comprises at least one of silicon dioxide (SiO₂) and silicon nitride (Si₃N₄).

15. The bulk acoustic resonator package of claim 1, wherein the cap melting member comprises a material that is based on a melting of a material, different from glass, and glass.

16. The bulk acoustic resonator package of claim 1, wherein the cap melting member has a width of 35 μm or more to 50 μm or less.

17. The bulk acoustic resonator package of claim 1, wherein a first portion of the surface of the cap facing the substrate is configured to protrude toward the substrate further than a second portion of the cap facing the substrate.

18. The bulk acoustic resonator package of claim 1, further comprising:
a hydrophobic layer disposed in at least one of between the resonance portion and the cap, and on a surface of the cap.

19. The bulk acoustic resonator package of claim 18, further comprising:
a connection pattern configured to have at least a portion, that penetrates through the cap, and configured to electrically connect to at least one of the first electrode and the second electrode, and configured to have at least a portion in contact with the hydrophobic layer.

20. The bulk acoustic resonator package of claim 1, further comprising:
a hydrophobic layer disposed on a surface opposing a surface facing the cap on the substrate; and
a connection pattern, configured to have at least a portion that penetrates through the substrate, and is configured to electrically connect to at least one of the first electrode and the second electrode, and configured to have a portion in contact with the hydrophobic layer.

21. A bulk acoustic resonator package, comprising:
a lower side component comprising at least one of silicon dioxide (SiO₂), silicon nitride (Si₃N₄), aluminum oxide (Al₂O₃), aluminum nitride (AlN), silicon (Si), and a piezoelectric material;
a cap comprising a glass material; and
a resonance portion comprising a first electrode, a piezoelectric layer, and a second electrode, stacked in a first direction in which the lower side component and the cap face each other, and disposed between the lower side component and the cap,
wherein the cap is configured to be welded to at least a portion of the lower side component.

22. The bulk acoustic resonator package of claim 21, wherein the lower side component comprises:
a substrate;
a support layer disposed between the substrate and the resonance portion;
an insulating layer disposed between the support layer and the substrate; and
a membrane layer disposed between the support layer and the resonance portion.

23. The bulk acoustic resonator package of claim 22, wherein the lower side component further comprises an insulating bonding member configured to be welded to the cap between the membrane layer and the cap.

24. The bulk acoustic resonator package of claim 22, further comprising:
a hydrophobic layer disposed in at least one of between the resonance portion and the cap, on a surface of the cap, and on a surface of the substrate.
